(19) United States
(12) Patent Application Publication
(10) Pub. No.: US 2025/0349570 A1
(43) Pub. Date: Nov. 13, 2025

(54) SEMICONDUCTOR PACKAGE MOLDING APPARATUS, SEMICONDUCTOR PACKAGE MOLDING SYSTEM AND SEMICONDUCTOR MOLDING METHOD

(71) Applicant: SAMSUNG ELECTRONICS CO., LTD., Suwon-si (KR)

(72) Inventors: Tae Ryong Kim, Suwon-si (KR); Kyong Hwan Koh, Suwon-si (KR); Woo Hyeong Kim, Suwon-si (KR); Jin-Woo Park, Suwon-si (KR); Jae Kyung Yoo, Suwon-si (KR); Hyeon Jun Jin, Suwon-si (KR)

(73) Assignee: SAMSUNG ELECTRONICS CO., LTD., Suwon-si (KR)

(21) Appl. No.: 19/009,593

(22) Filed: Jan. 3, 2025

(30) Foreign Application Priority Data
May 9, 2024 (KR) 10-2024-0060975

(51) Int. Cl. H01L 21/67; H01L 21/56; H01L 21/677

(52) U.S. Cl. CPC H01L 21/67126; H01L 21/565; H01L 21/67742

(57) ABSTRACT

A semiconductor package molding apparatus includes a chamber including: a first chamber structure including a first mold on which a molding target is configured to be seated; a second chamber structure configured to be clamped to the first chamber structure such as to isolate an interior of the chamber from an exterior of the chamber, the second chamber structure including a second mold, wherein the first mold and the second mold are configured to form a first cavity therebetween; and a first vacuum configured to discharge air from the first cavity. The semiconductor package molding apparatus further includes preloader on a side face of the chamber, the preloader including: a second cavity; a third mold configured to have a molding material seated thereon; a second vacuum configured to discharge air from the second cavity, and a first transfer arm configured to seat the molding material on the second mold.

### CROSS-REFERENCE TO RELATED APPLICATION

This application claims priority from Korean Patent Application No. 10-2024-0060975 filed on May 9, 2024, in the Korean Intellectual Property Office, and all the benefits accruing therefrom under 35 U.S.C. 119, the contents of which in their entireties are incorporated herein by reference.

### BACKGROUND

### 1. Field

Embodiments of the present disclosure relate to a semiconductor package molding apparatus, a semiconductor package molding system, and a semiconductor package molding method.

### 2. Description of Related Art

A molding process of molding a semiconductor chip is used to protect the semiconductor chip when fabricating a semiconductor package. The molding process may be performed by a compression molding type in which a semiconductor package and a molding material are each positioned inside an upper molding die and a lower molding die, and the upper molding die and the lower molding die are clamped to encapsulate the semiconductor package with the molding material. At this time, cavities in the upper molding die and the lower molding die need to be kept in a vacuum, so that voids are not formed in a molded underfill during the compression molding process. Such voids may cause problems such as bump extrusion in subsequent processes.

### SUMMARY

According to some embodiments of the present disclosure, a semiconductor package molding apparatus may be provided that may alleviate defects caused by voids occurring in a molded underfill.

According to some embodiments of the present disclosure, a semiconductor package molding system may be provided that may alleviate defects caused by voids occurring in the molded underfill.

According to some embodiments of the present disclosure, a semiconductor package molding method may be provided that may alleviate defects caused by voids occurring in the molded underfill.

According to some embodiments of the present disclosure, a semiconductor package molding apparatus may be provided and include a chamber including: a first chamber structure including a first mold on which a molding target is configured to be seated; a second chamber structure configured to be clamped to the first chamber structure such as to isolate an interior of the chamber from an exterior of the chamber, the second chamber structure including a second mold including a first heater, wherein the first mold and the second mold are configured to form a first cavity between the first mold and the second mold; and a first vacuum configured to discharge air from the first cavity. The semiconductor package molding apparatus may further include preloader on a side face of the chamber, the preloader including: a second cavity; a third mold configured to have a molding material seated thereon; a second vacuum configured to discharge air from the second cavity, and a first transfer arm configured to seat the molding material on the second mold.

According to some embodiments of the present disclosure, a semiconductor package molding system may be provided and include: a molding material discharger configured to discharge and transfer a molding material; a molding material transferor configured to receive and transfer the molding material from the molding material discharger; a molding target transferor configured to transfer a molding target; a presser configured to perform a compression molding process on the molding target, using the molding material; and a preloader including: a first cavity; a stage on which the molding material is configured to be seated; a first vacuum configured to discharge air from the first cavity; and a first transfer arm configured to transfer the molding material to the presser, wherein the presser includes: a first chamber structure including a first mold on which the molding target is configured to be seated; a second chamber structure including a second mold including a heater, the first mold and the second mold configured to form a second cavity between the first mold and the second mold; and a second vacuum configured to discharge air of the second cavity, wherein the first chamber structure and the second chamber structure are configured to be clamped to each other to perform the compression molding process.

According to some embodiments of the present disclosure, a semiconductor package molding method may be provided and include: seating a molding material on a stage of a preloader, wherein the preloader is on a side face of a chamber, and the chamber includes a first chamber structure including a first mold, and a second chamber structure including a second mold including a first heater, wherein a first cavity is between the first mold and the second mold; sucking, by a first vacuum of the preloader, air inside a second cavity of the preloader and discharging the air to an outside of the preloader; transferring, by a first transfer arm of the preloader and after the sucking the air, the molding material seated on the stage to the second mold, such that the molding material is seated on the second mold; heating, by the first heater, the molding material seated on the second mold for a first time period; and clamping, after the heating for the first time period, the first chamber structure and the second chamber structure such that a molding target seated on the first mold is encapsulated with the molding material.

However, aspects of embodiments of the present disclosure are not restricted to the ones set forth above. The above and other aspects of embodiments of the present disclosure will become more apparent to one of ordinary skill in the art to which the present disclosure pertains by referencing the detailed description of the present disclosure given below.

It should be noted that effects of embodiments of the present disclosure are not limited to those described above, and other effects of embodiments of the present disclosure will be apparent from the following description.

### BRIEF DESCRIPTION OF DRAWINGS

The above and other aspects and features of embodiments of the present disclosure will become more apparent by describing in detail non-limiting example embodiments of the present disclosure with reference to the attached drawings, in which:

FIG. 1 is a diagram for explaining a semiconductor package molding system according to some embodiments.

FIG. 2 is a diagram showing a movement path of a molding target in a semiconductor package molding system according to some embodiments.

FIG. 3 is a diagram showing a movement path of a molding material in a semiconductor package molding system according to some embodiments.

FIG. 4 is a diagram for explaining a semiconductor package molding apparatus according to some embodiments.

FIG. 5 is a diagram for explaining a molding target transfer unit of a semiconductor package molding system according to some embodiments.

FIG. 6 is a diagram for explaining a first transfer arm of the semiconductor package molding apparatus according to some embodiments.

FIGS. 7 to 12 are diagrams for explaining the first transfer arm of FIG. 6.

FIG. 13 is a diagram for explaining a semiconductor package molding apparatus according to some embodiments.

FIG. 14 is a diagram showing a movement path of a molding target in the semiconductor package molding system according to some embodiments.

FIG. 15 is a diagram for explaining a molding target transfer unit of the semiconductor package molding system according to some embodiments.

FIG. 16 is a diagram for explaining a second transfer arm of a preloader according to some embodiments.

FIG. 17 is a diagram for explaining the second transfer arm of FIG. 16.

FIGS. 18 and 19 are diagrams showing each of a movement path of the molding target and a movement path of a molding material in the semiconductor package molding system according to some embodiments.

FIG. 20 is a flowchart for explaining a semiconductor package molding method according to some embodiments.

FIGS. 21 to 28 are intermediate stage diagrams for explaining the semiconductor package molding method of FIG. 20.

FIG. 29 is a flowchart for explaining a semiconductor package molding method according to some embodiments.

FIGS. 30 to 38 are intermediate stage diagrams for explaining the semiconductor package molding method of FIG. 29.

FIGS. 39 to 44 are intermediate stage diagrams for explaining the semiconductor package molding method of FIG. 29.

### DETAILED DESCRIPTION

Hereinafter, a semiconductor package molding apparatus, a semiconductor package molding system, and a semiconductor package molding method according to some embodiments of the present disclosure will be described with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

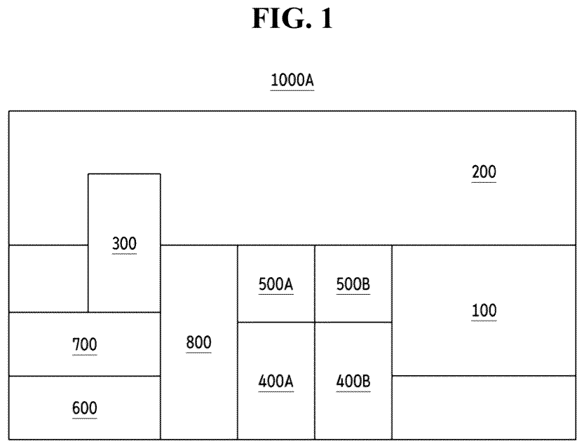

FIG. 1 is a diagram for explaining a semiconductor package molding system according to some embodiments.

Referring to FIG. 1, a semiconductor package molding system 1000A may include a molding material discharge unit 100 (e.g., a molding material discharger), a molding material transfer unit 200 (e.g., a molding material transferor), a molding target transfer unit 300 (e.g., a molding target transferor), a press unit 400A (e.g., a presser), a press unit 400B (e.g., a presser), a preloader 500A, a preloader 500B, a load port 600, a handler 700, and an aligner 800.

The semiconductor package molding system 1000A may be a system that fabricates a semiconductor package by performing a compression molding process in which a molding target and a molding material are carried into one of the press units (e.g., the press unit 400A or the press unit 400B), and then the molding target is encapsulated with the molding material. The molding target may be a material that is encapsulated with the molding material.

For example, the molding target may be a wafer level semiconductor package in which at least one semiconductor chip is stacked on a substrate. For example, the molding target may include a structure in which at least one semiconductor chip is mounted on a substrate, and the semiconductor chip on the substrate is connected to the substrate through a plurality of bumps.

Although the molding material may include epoxy mold compound (EMC), embodiments of the present disclosure are not limited thereto. The molding material may be in a solid form and may be liquefied to have fluidity when heated.

As shown in FIG. 1, the semiconductor package molding system 1000A may include a plurality of zones. Each of the plurality of zones of the semiconductor package molding system 1000A may provide a space for performing a specific process on the molding target or the molding material. Furthermore, each of the plurality of zones of the semiconductor package molding system 1000A may be a passage for transferring a molding target or a molding material. Also, each of the plurality of zones of the semiconductor package molding system 1000A may be a passage for transferring a semiconductor package fabricated by performing a compression molding process inside either of the press units (e.g., the press unit 400A or the press unit 400B).

The molding material discharge unit 100 may be configured to discharge and transfer the molding material. The molding material transfer unit 200 may receive the molding material discharged from the molding material discharge unit 100 from the molding material discharge unit 100. The molding material transfer unit 200 may transfer the received molding material to another zone in the semiconductor package molding system 1000A. For example, the molding material transfer unit 200 may transfer the molding material to any one of the preloaders (e.g., the preloader 500A or the preloader 500B). The molding material transfer unit 200 may be a transfer robot for transferring the molding material to another zone in the semiconductor package molding system 1000A.

The preloaders (e.g., the preloader 500A and the preloader 500B) may perform a specific process on the molding material carried into an interior of the preloader, and then transfer the molding material to the inside of the press units (e.g., the press unit 400A and the press unit 400B). Taking the preloader 500A as an example, in a state in which a molding material is carried into the preloader 500A, the air inside the preloader 500A may be sucked using a vacuum unit (e.g., a vacuum) and may be discharged to the outside of the preloader 500A. After performing vacuum suction until the vacuum level inside the preloader 500A reaches a target vacuum level, the molding material inside the preloader 500A may be transferred to the press unit 400A.

The load port 600, the handler 700, and the aligner 800 may constitute an equipment front end module (EFEM). The EFEM may be an apparatus that transfers the molding target stored in an front opening unified pod (FOUP) to the inside of the preloaders (e.g., the preloader 500A and the preloader 500B) and the press units (e.g., the press unit 400A and the press unit 400B).

The load port 600 may be a space for connecting the FOUP and the EFEM. The load port 600 may provide a space independent of the outside so that external air or impurities do not flow in when the molding target stored in the FOUP is moved to the EFEM. The handler 700 may be a transfer robot for transferring the molding target disposed in the load port 600 to the aligner 800 or transferring the molding target disposed in the aligner 800 to the molding target transfer unit 300. The aligner 800 may receive the molding target from the handler 700. The aligner 800 may align the wafer by sensing a notch of the wafer using a sensor (e.g., a sensor of the aligner 800), while rotating the wafer of the molding target.

The molding target transfer unit 300 may receive the molding target in an aligned state from the handler 700 and transfer it to another zone in the semiconductor package molding system 1000. For example, the molding target transfer unit 300 may transfer the molding target to any one from among the preloaders (e.g., the preloader 500A and the preloader 500B). The molding target may be carried into the press unit 400A via the preloader 500A, or may be carried into the press unit 400B via the preloader 500B.

At this time, the molding target carried into the preloader 500A may be subjected to a specific process in the preloader 500A, and then the molding target may be carried into the press unit 400A. Similarly, the molding target carried into the preloader 500B may be subjected to a specific process in the preloader 500B, and then the molding target may be carried into the press unit 400B.

However, embodiments of the present disclosure are not limited thereto, and the molding target carried into the preloader 500A may be carried into the press unit 400A simply by passing through the preloader 500A without being subjected to a specific process in the preloader 500A. Similarly, the molding target carried into the preloader 500B may be carried into the press unit 400B by simply passing through the preloader 500B without being subjected to a specific process inside the preloader 500B.

Although FIG. 1 shows that the semiconductor package molding system 1000A includes each of two preloaders (e.g., a preloader 500A and a preloader 500B) and two press units (e.g., a press unit 400A and a press unit 400B), embodiments of the present disclosure are not limited thereto. For example, the semiconductor package molding system 1000A may include one preloader and one press unit. Alternatively, the semiconductor package molding system 1000A may include three or more preloaders and three or more press units.

The preloaders and the press units included in the semiconductor package molding system 1000A may correspond to each other so as to be paired. For example, the preloader 500A may correspond to the press unit 400A, and the preloader 500B may correspond to the press unit 400B.

When the molding target and the molding material are carried into the inside of the press unit, the molding target and the molding material may be transferred into the inside of the press unit via a preloader corresponding to the press unit into which they are carried. In addition, a semiconductor package fabricated by the compression molding process performed in the press unit may be transferred to the molding target transfer unit 300 via the preloader corresponding to the press unit.

For example, the molding target may be carried into the press unit 400A from the molding target transfer unit 300 via the preloader 500A, or may be carried into the press unit 400B from the molding target transfer unit 300 via the preloader 500B. Also, the molding material may be carried into the press unit 400A from the molding material transfer unit 200 via the preloader 500A, or may be carried into the press unit 400B from the molding material transfer unit 200 via the preloader 500B.

For example, a semiconductor package fabricated by performing a compression molding process in the press unit 400A may be transferred to the molding target transfer unit 300 via the preloader 500A. Also, a semiconductor package fabricated by performing a compression molding process in the press unit 400B may be transferred to the molding target transfer unit 300 via the preloader 500B.

The description of the preloader 500B overlaps the description of the preloader 500A, and the description of the press unit 400B overlaps the description of the press unit 400A. Accordingly, the preloader 500A and the press unit 400A will be mainly explained, and the preloader 500B and the press unit 400B may be understood from the explanation of the preloader 500A and the press unit 400A.

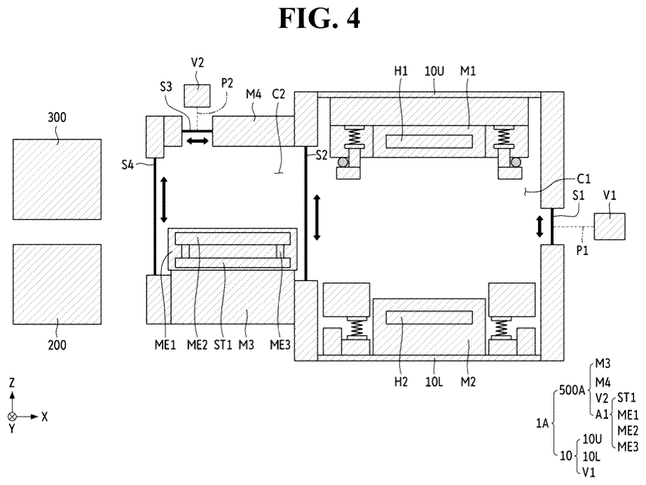

The press unit 400A may be provided on a side face of the preloader 500A. The press unit 400A may receive the molding target and the molding material from the preloader 500A. The press unit 400A may perform a compression molding process in which the molding target is encapsulated with the molding material. The preloader 500A and the press unit 400A will be described later with reference to FIG. 4 and the like.

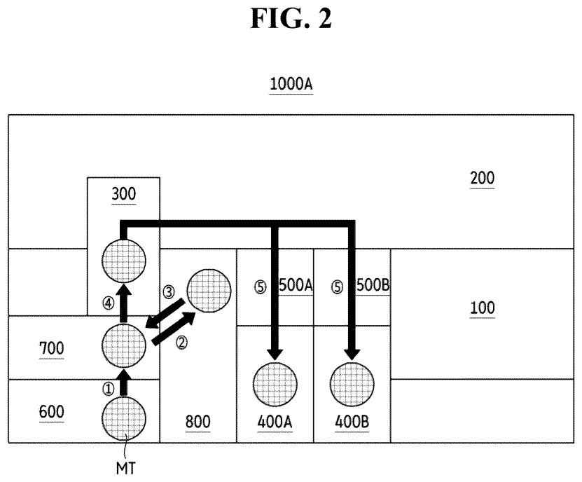

FIG. 2 is a diagram showing a movement path of a molding target in a semiconductor package molding system according to some embodiments.

FIG. 2 shows a transfer path in which the molding target MT is transferred from the load port 600 to the press units (e.g., the press unit 400A and the press unit 400B) in the semiconductor package molding system 1000A. Referring to FIG. 2, the molding target MT input into the semiconductor package molding system 1000 may be transferred to the aligner 800 by the handler 700 via the load port 600. The aligner 800 may receive the molding target MT from the handler 700 and align the molding target MT. The molding target MT, after being aligned, may be transferred to the molding target transfer unit 300 by the handler 700. The molding target transfer unit 300 may transfer the molding target MT to either the preloader 500A or the preloader 500B. A case where the molding target transfer unit 300 transfers the molding target MT to the preloader 500A will be explained below.

In some embodiments, a specific process of the molding target MT may not be performed in the preloader 500A. At this time, the molding target transfer unit 300 may transfer the molding target MT immediately to the press unit 400A via the preloader 500A. However, the movement path of the molding target MT shown in FIG. 2 is an example, and the movement path of the molding target MT in the semiconductor package molding system 1000A may change depending on the embodiment.

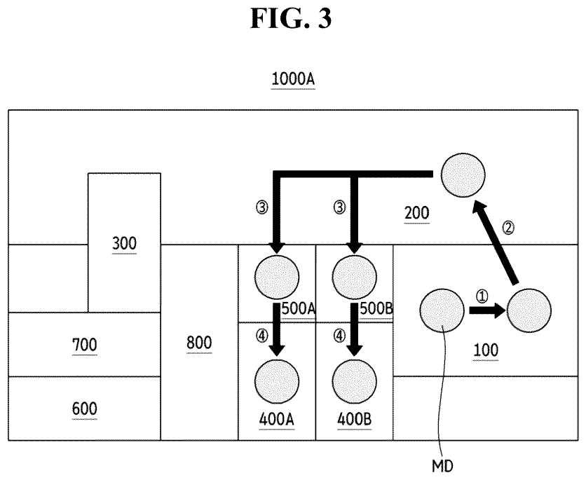

FIG. 3 is a diagram showing the movement path of the molding material in a semiconductor package molding system according to some embodiments.

FIG. 3 shows the transfer path in which the molding material MD is carried from the molding material discharge unit 100 into the press units (e.g., the press unit 400A and the press unit 400B) in the semiconductor package molding system 1000A. Referring to FIG. 3, the molding material MD may be discharged from the molding material discharge unit 100 and transferred to the molding material transfer unit 200. The molding material transfer unit 200 may receive the molding material MD from the molding material discharge unit 100, and transfer the molding material MD to either the preloader 500A or the preloader 500B. Hereinafter, a case where the molding material transfer unit 200 transfers the molding material MD to the preloader 500A will be described as an example.

In some embodiments, a process of increasing the degree of vacuum inside the preloader 500A by discharging air inside the preloader 500A while the molding material M is transferred into the preloader 500A by the molding material transfer unit 200 may be performed. Next, a transfer arm inside the preloader 500A may transfer the molding material MD to the press unit 400A. The molding target MT and the molding material MD may be provided to the inside of the press unit 400A through the transfer paths of the molding target MT and the molding material M shown in FIGS. 2 and 3, respectively.

FIG. 4 is a diagram for explaining a semiconductor package molding apparatus according to some embodiments.

Referring to FIG. 4, a first direction X and a second direction Y may be directions that intersect with each other among horizontal directions. For example, the first direction X and the second direction Y may be directions that perpendicularly intersect each other. A third direction Z may be a direction that intersects both the first direction X and the second direction Y. For example, the third direction Z may be a direction perpendicular to the first direction X and the second direction Y. Therefore, the first direction X, the second direction Y, and the third direction Z may be directions orthogonal to each other. Hereinafter, an upper direction or an upper face will be explained on the basis of the third direction Z, and a lower direction or a lower face will be explained on the basis of a direction opposite to the third direction Z.

Referring to FIG. 4, a semiconductor package molding apparatus 1A may include a chamber 10 and a preloader 500A. A molding target transfer unit 300 and a molding material transfer unit 200 may be provided on the side face of the preloader 500A.

The chamber 10 may be included in the press unit 400A of the semiconductor package molding system 1000A. The chamber 10 may be a housing that forms an outside of the semiconductor package molding apparatus 1A. The chamber 10 may include a first chamber structure 10U, a second chamber structure 10L, and a first vacuum unit V1 (e.g., a first vacuum). The first chamber structure 10U may be disposed above the second chamber structure 10L. The first chamber structure 10U and the second chamber structure 10L may be clamped to each other. The chamber 10 may isolate an inside of the chamber 10 from an outside of the chamber 10, and when a compression molding process is performed inside the chamber 10, the inside of the chamber 10 may be maintained in a vacuum unlike the outside.

The first chamber structure 10U may include a first mold M1, and the second chamber structure 10L may include a second mold M2. When the first chamber structure 10U and the second chamber structure 10L are clamped to each other, the first chamber structure 10U is fixed, and the second chamber structure 10L may be spaced apart from or coupled to the first chamber structure 10U, while moving up and down. However, embodiments of the present disclosure are not limited thereto. For example, in the semiconductor package molding apparatus 1A according to some embodiments, the first chamber structure 10U may move up and down while the second chamber structure 10L is fixed, or both the first chamber structure 10U and the second chamber structure 10L may move up and down.

The molding target W (shown in FIG. 2) may be seated on the first mold M1. The molding material MD (shown in FIG. 3) may be seated on the second mold M2. When the first chamber structure 10U and the second chamber structure 10L are coupled with each other while the molding target MT is seated on the first mold M1, a first cavity C1 may be formed between the first mold M1 and the second mold M2. That is, the first cavity C1 may be a space between the first mold M1 and the second mold M2.

The first mold M1 may include a first heating unit H1 (e.g., a first heater). The first heating unit H1 may be configured to heat the molding target MT seated on the first mold M1. For example, the molding target MT may be heated by the first heating unit H1 from the moment at which the molding target MT is seated on the first mold M1. The second mold M2 may include a second heating unit H2 (e.g., a second heater). The second heating unit H2 may be configured to heat the molding material MD seated on the second mold M2. For example, the molding material MD may be heated by the second heating unit H2 from the moment at which the molding material MD is seated on the second mold M2. The first heating unit H1 and the second heating unit H2 may each be embodied by a heater.

The first vacuum unit V1 may be connected to a first air discharge passage P1. The first vacuum unit V1 may discharge the air inside the first cavity C1 to the outside of the chamber 10 through the first air discharge passage P1. The first vacuum unit V1 may be a dry pump, or may be embodied in the form of a roots type rotor, a screw type rotor, or a combination of the roots type rotor and the screw type rotor inside. The roots type rotor is connected to the chamber 10 and may suck the air inside the first cavity C1. The screw type rotor may discharge the air sucked from the roots type rotor to the outside of the chamber 10.

The preloader 500A may be formed on the side face of the chamber 10. The preloader 500A and the chamber 10 may be disposed side by side with each other along the first direction X. The preloader 500A may include a third mold M3, a fourth mold M4, a second vacuum unit V2 (e.g., a second vacuum), and a first transfer arm A1. The fourth mold M4 may be disposed above the third mold M3. The molding material MD may be disposed on the third mold M3, and the molding target MT may be disposed on the fourth mold M4. The preloader 500A may include a second cavity C2 therein. At this time, the second cavity C2 may be a space between the third mold M3 and the fourth mold M4.

The second vacuum unit V2 may be connected to a second air discharge passage P2. The second vacuum unit V2 may discharge the air inside the second cavity C2 to the outside of the preloader 500A through the second air discharge passage P2. The second vacuum unit V2 may be a dry pump, or may be embodied as a roots type rotor, a screw type rotor or in the combined form of the roots type rotor and the screw type rotor inside. The roots type rotor may be connected to the preloader 500A to suck air inside the second cavity C2. In addition, the screw type rotor may discharge the air sucked from the roots type rotor to the outside of the preloader 500A.

A first shutter S1 and a second shutter S2 may be formed between the first chamber structure 10U and the second chamber structure 10L. The first shutter S1 may be formed on one side of the chamber 10, and the second shutter S2 may be formed on the other side of the chamber 10. The first shutter S1 and the second shutter S2 may each be configured to be openable and closable.

For example, the first shutter S1 may be opened when air inside the first cavity C1 is sucked using the first vacuum unit V1 and discharged to the outside of the chamber 10. In addition, the first shutter S1 may be closed when the first chamber structure 10U and the second chamber structure 10L are clamped together to perform the compression molding process.

For example, the second shutter S2 may be disposed between the chamber 10 and the preloader 500A. The second shutter S2 may physically separate the first cavity C1 and the second cavity C2. The second shutter S2 may be opened when the molding target MT or the molding material is transferred from the preloader 500A to the chamber 10. In addition, the second shutter S2 may be closed to physically separate the first cavity C1 and the second cavity C2. For example, when the first chamber structure 10U and the second chamber structure 10L are clamped together to perform the compression molding process, the second shutter S2 may be closed when the air of the first cavity C1 is discharged to the outside of the chamber 10 by using the first vacuum unit V1, or when the air of the second cavity C2 is discharged to the outside of the preloader 500A by using the second vacuum unit V2.

The preloader 500A may include a third shutter S3 and a fourth shutter S4. The third shutter S3 may be formed in the fourth mold M4, and the fourth shutter S4 may be formed between the third mold M3 and the fourth mold M4. The third shutter S3 and the fourth shutter S4 may each be configured to be openable and closable.

For example, the third shutter S3 may be opened when air inside the second cavity C2 is sucked using the second vacuum unit V2 and discharged to the outside of the preloader 500A. The fourth shutter S4 may be opened when the molding target transfer unit 300 seats the molding target MT on the fourth mold M4 of the preloader 500A or seats it on the first mold M1 of the chamber 10. The fourth shutter S4 may also be opened when the molding material transfer unit 200 seats the molding material MD on the third mold M3 of the preloader 500A or seats it on the second mold M2 of the chamber 10. The fourth shutter S4 may be closed when the air inside the second cavity C2 is sucked using the second vacuum unit V2 and discharged to the outside of the preloader 500A.

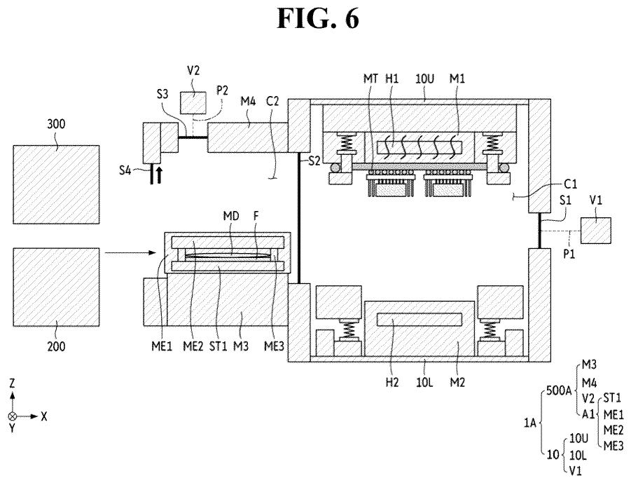

The first transfer arm A1 may receive the molding material MD from the molding material transfer unit 200. The first transfer arm A1 may also be configured to seat the molding material MD received from the molding material transfer unit 200 on the second mold M2 of the chamber 10. The first transfer arm A1 may include a stage ST1, a first member ME1, a second member ME2, and a third member ME3. The first transfer arm A1 will be described below with reference to FIGS. 6 to 12.

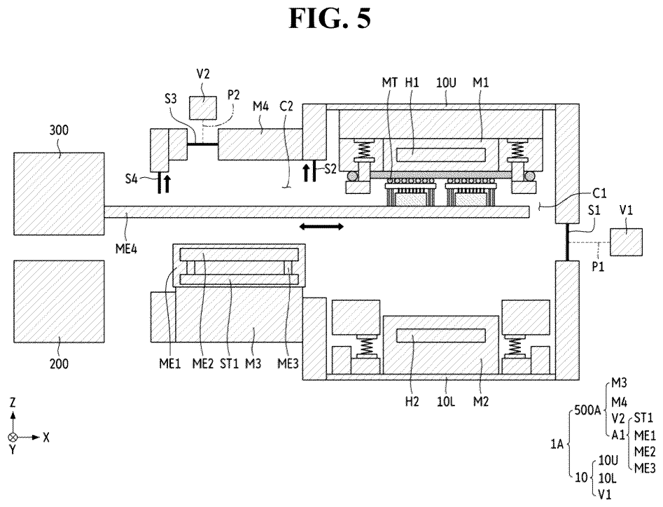

FIG. 5 is a diagram for explaining a molding target transfer unit of a semiconductor package molding system according to some embodiments.

Referring to FIG. 5, a fourth member ME4 may be mounted on one side of the molding target transfer unit 300. One end of the fourth member ME4 may be connected to one side of the molding target transfer unit 300, and the other end of the fourth member ME4 may face the preloader 500A and the chamber 10. The fourth member ME4 may slide from the molding target transfer unit 300 along the first direction X.

FIG. 5 shows the time at which the fourth member ME4 slides maximally from the molding target transfer unit 300 along the first direction X. As shown in FIG. 5, when the fourth member ME4 slides maximally from the molding target transfer unit 300 along the first direction X, the other end of the fourth member ME4 may reach the edge portion of the chamber 10. Accordingly, the fourth member ME4 of the molding target transfer unit 300 may seat the molding target MT on the first mold M1.

In some embodiments, the fourth member ME4 may slide until the other end reaches the boundary between the preloader 500A and the chamber 10. At this time, the fourth member ME4 of the molding target transfer unit 300 may seat the molding target MT on the fourth mold M4. That is, a sliding range of the fourth member ME4 of the molding target transfer unit 300 is variable depending on whether the molding target MT is seated on the first mold M1 or the fourth mold M4.

Also, when the fourth member ME4 slides from the molding target transfer unit 300 along the first direction X to seat the molding target MT on the fourth mold M4, the fourth shutter S4 may be opened. Also, when the fourth member ME4 slides from the molding target transfer unit 300 along the first direction X to seat the molding target MT on the first mold M1, the second shutter S2 may be opened.

FIG. 6 is a diagram for explaining the first transfer arm of the semiconductor package molding apparatus according to some embodiments.

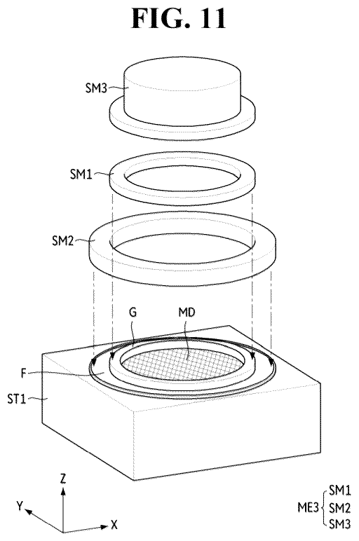

Referring to FIG. 6, the first transfer arm A1 may include the first stage ST1, the first member ME1, the second member ME2, and the third member ME3. The first transfer arm A1 may receive the molding material MD from the molding material transfer unit 200. At this time, the fourth shutter S4 may be opened. The first stage ST1 may include an upper face on which the molding material MD is seated. At this time, the molding material MD may be seated on the first stage ST1 with a film F sandwiched therebetween. The first member ME1 may be disposed on the third mold M3. The second member ME2 may be mounted on the first member ME1. At this time, the second member ME2 may slide onto the second mold M2 from the first member ME1 along the first direction X. The third member ME3 that grips the molding material MD seated on the first stage ST1 may be formed on the lower face of the second member ME2. The third member ME3 will be described below with reference to FIG. 11 and the like.

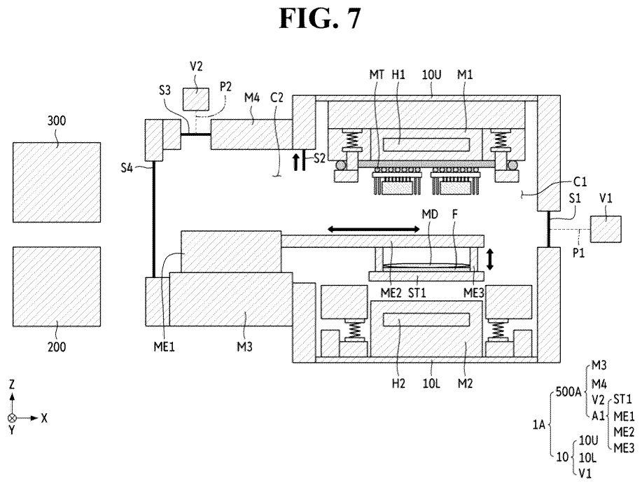

FIGS. 7 to 12 are diagrams for explaining the first transfer arm of FIG. 6.

First, referring to FIG. 7, in the state in which the molding material MD is seated on the first stage ST1, the second member ME2 may slide from the first member ME1 along the first direction X. Accordingly, the first stage ST1 on which the molding material MD is seated may be moved onto the second mold M2. The third member ME3 may move in the third direction Z and in a direction opposite to the third direction Z. When the second member ME2 slides along the first direction X and the first stage ST1 is positioned on the second mold M2, the third member ME3 may move in the direction opposite to the third direction Z. Accordingly, the molding material MD may be seated on the second mold M2. Also, when the second member ME2 slides from the first member ME1 along the first direction X, the second shutter S2 may be opened.

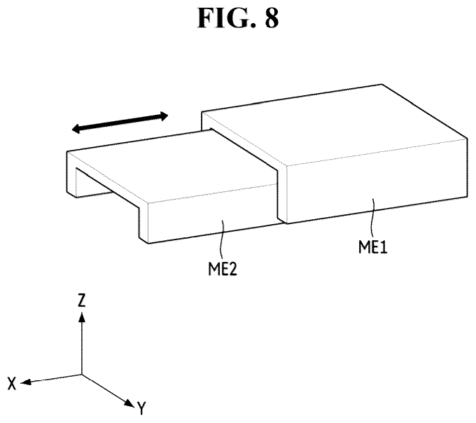

Next, FIGS. 8 to 12 are diagrams for explaining the first stage ST1, the first member ME1, the second member ME2, and the third member ME3 that form the first transfer arm A1 in more detail. First, referring to FIG. 8, the first member ME1 and the second member ME2 may each include a rectangular shell shape. The second member ME2 may have a shape smaller than a shape of the first member ME1. The second member ME2 slides in the direction opposite to the first direction X, and may be accommodated inside the first member ME1 to completely overlap with the first member ME1. In addition, the second member ME2 may slide in the first direction X from the first member ME1, while being mounted on the first member ME1.

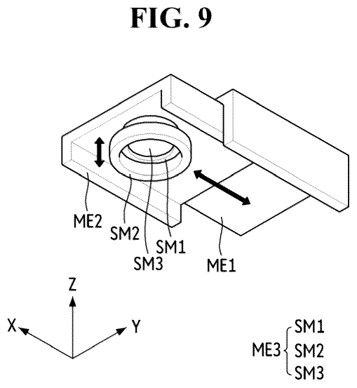

Next, referring to FIG. 9, FIG. 9 is a diagram of the first member ME1 on which the second member ME2 is mounted, as viewed from below. The third member ME3 may be disposed on the lower face of the second member ME2. The third member ME3 may include a plurality of sub-members. For example, the third member ME3 may include a first sub-member SM1, a second sub-member SM2, and a third sub-member SM3. The first sub-member SM1, the second sub-member SM2, and the third sub-member SM3 will be described below referring to FIG. 11.

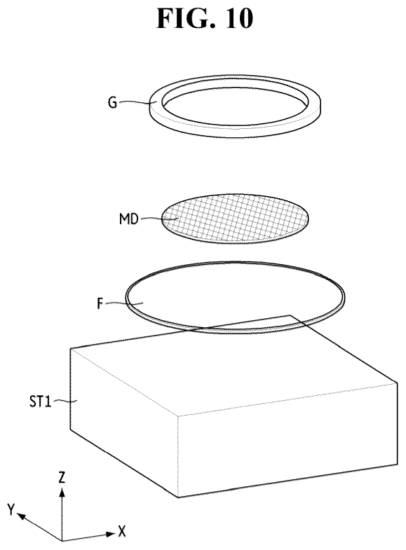

Next, referring to FIG. 10, FIG. 10 is an exploded perspective view showing a film F, a molding material MD, and a molding material guide frame G disposed on the first stage ST1. The film F may be disposed on the upper face of the first stage ST1, and the molding material MD may be disposed on the film F. Also, the molding material guide frame G may be disposed on the molding material MD. The molding material guide frame G may provide a guide frame for the third member ME3 to grip the molding material MD.

Next, referring to FIG. 11, FIG. 11 is an exploded perspective view for explaining an example in which third member ME3 grips the configurations on the first stage ST1. When the third member ME3 grips the molding material MD, the second sub-member SM2 may grip the film F by vacuum suction. In addition, the first sub-member SM1 may grip the molding material guide frame G. The first sub-member SM1 and the second sub-member SM2 may overlap with each other. The third sub-member SM3 may be provided between the lower face of the second member ME2 and the first sub-member SM1, and may be configured to connect the second member ME2 and the first sub-member SM1 to each other.

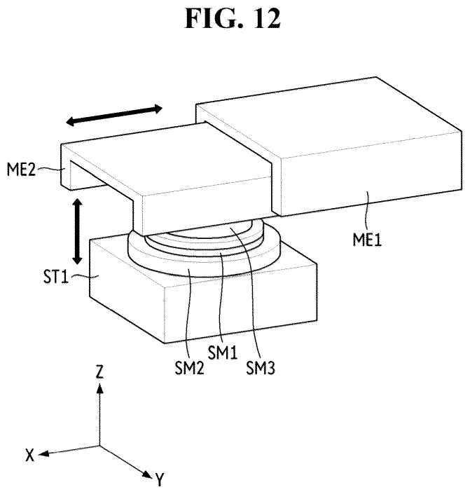

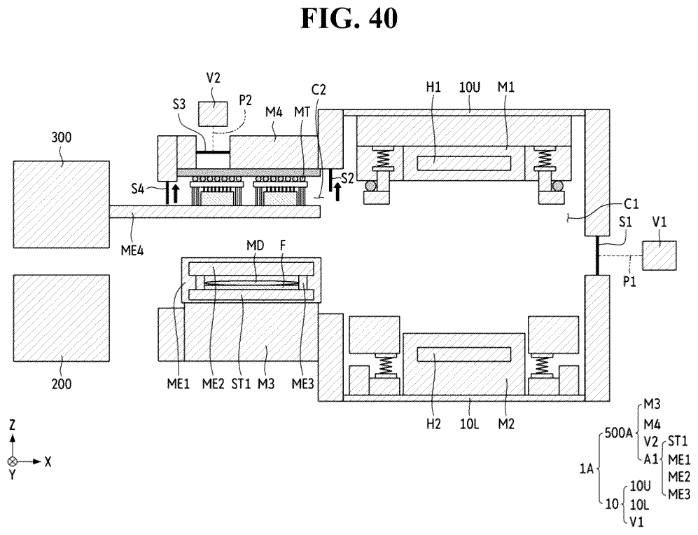

Next, referring to FIG. 12, the operation of the first transfer arm A1 will be described. The second member ME2 of the first transfer arm A1 is mounted on the first member ME1 and may move, while sliding from the first member ME1 along the first direction X, and the third member ME3 that grips the molding material MD may be formed on the lower face of the second member ME2. The second member ME2 of the first transfer arm A1 slides from the first member ME1 along the first direction X, and when the first stage ST1 of the first transfer arm A1 is positioned on the second mold M2 (shown in FIG. 40), the third sub-member SM3 may extend along the direction opposite to the third direction Z. Accordingly, the first stage ST1 on which the molding material MD is seated may move in the direction opposite to the third direction Z and may be seated on the second mold M2.

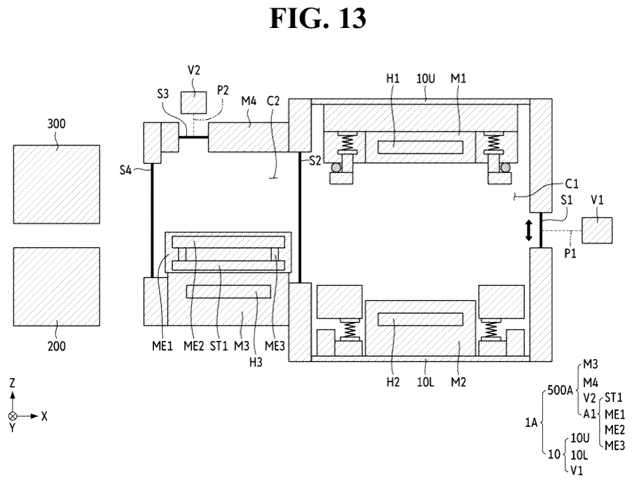

FIG. 13 is a diagram for explaining a semiconductor package molding apparatus according to some embodiments.

Referring to FIG. 13, the semiconductor package molding apparatus 1A may further include a third heating unit H3 (e.g., a third heater). The third mold M3 may include the third heating unit H3. The third heating unit H3 may be configured to heat the molding material MD (shown in FIG. 3) seated on the third mold M3. For example, when the molding material MD is seated on the third mold M3, air inside the second cavity C2 may be sucked using the second vacuum unit V2 and discharged to the outside of the preloader 500A. At this time, the second vacuum unit V2 may continue to perform the vacuum suction, until the vacuum degree inside the second cavity C2 reaches a target vacuum degree. Thereafter, when the vacuum degree inside the second cavity C2 reaches the target vacuum degree, the third heating unit H3 may heat the molding material MD on the third mold M3. After the molding material MD on the third mold M3 is heated for a predetermined period of time, the first transfer arm A1 may transfer the molding material MD so that the molding material MD is seated on the second mold M2 through the method described with reference to FIGS. 7 to 12.

When the molding material MD seated on the second mold M2 inside the chamber 10 with a high degree of vacuum is heated and melted by the second heating unit H2, a large amount of gas may be generated. In a comparative embodiment, the gas generated at this time may contribute to the generation of voids in the molded underfill (MUF) at the time of the compression molding process. In some embodiments of the present disclosure, after the degree of vacuum of the molding material MD is lowered in advance with the molding material MD loaded into the preloader 500A, before the molding material MD that has reached the target vacuum degree is transferred to the chamber 10, the molding material MD may be preheated for a certain period of time by the preloader 500A. Accordingly, it is possible to alleviate a phenomenon in which a large amount of gas is emitted when the molding material MD is heated by the second heating unit H2, when performing the compression molding process of encapsulating the molding target MT (shown in FIG. 5) using the molding material MD moved from the preloader 500A to the chamber 10. Accordingly, it is possible alleviate a phenomenon of voids being generated in the MUF of the semiconductor package that is finally fabricated by the compression molding process.

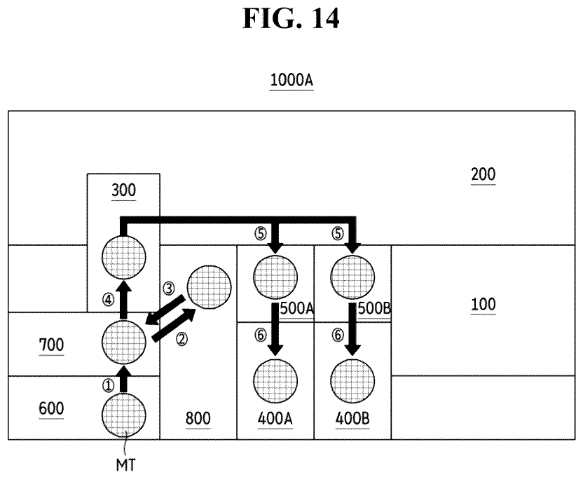

FIG. 14 is a diagram showing a movement path of the molding target in the semiconductor package molding system according to some embodiments. Hereinafter, descriptions that are the same as or similar to the description of the previously-described embodiments may be omitted, and differences will be mainly described.

Referring to FIG. 14, in the semiconductor package molding system 1000A, unlike as shown in FIG. 2, when the molding target MT is transferred from the molding target transfer unit 300 to the press unit 400A via the preloader 500A, the molding target MT may not be immediately transferred to the press unit 400A. That is, a specific process is first performed on the molding target MT inside the preloader 500A, and then the molding target MT after the process is completed may be transferred to the press unit 400A. For example, in the state in which both the molding target MT and the molding material MD (shown in FIG. 3) are loaded into the preloader 500A, a process of sucking air inside the second cavity C2 of the preloader 500A (shown in FIG. 4) and discharging the air to the outside of the preloader 500A may be performed. After that process is completed, the molding target MT and the molding material MD are transferred to the chamber 10 of the press unit 400A, and a compression molding process of encapsulating the molding target MT using the molding material MD may be performed.

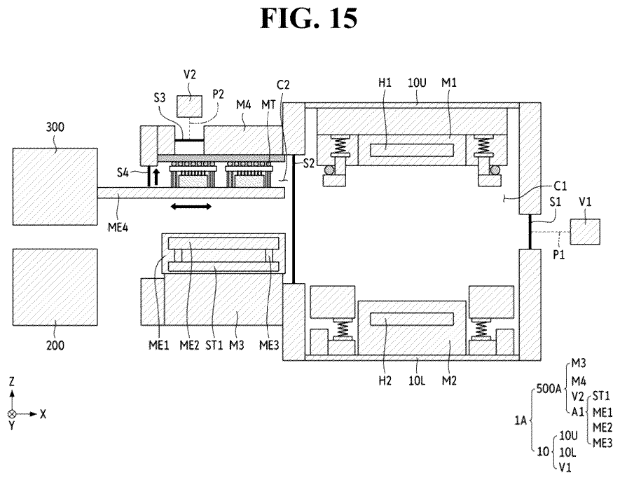

FIG. 15 is a diagram for explaining the molding target transfer unit of the semiconductor package molding system according to some embodiments.

Referring to FIG. 15, the fourth member ME4 may slide from the molding target transfer unit 300 along the first direction X in the state of seating the molding target MT on the upper face of the fourth member ME4. At this time, unlike as shown in FIG. 5, the fourth member ME4 may slide until the other end of the fourth member ME4 reaches the boundary portion between the preloader 500A and the chamber 10. That is, the fourth member ME4 may slide only to a position where the molding target MT may be seated on the fourth mold M4, and then the molding target MT may be seated on the fourth mold M4. Also, when the fourth member ME4 slides from the molding target transfer unit 300 along the first direction X, the second shutter S2 may be closed and the fourth shutter S4 may be opened.

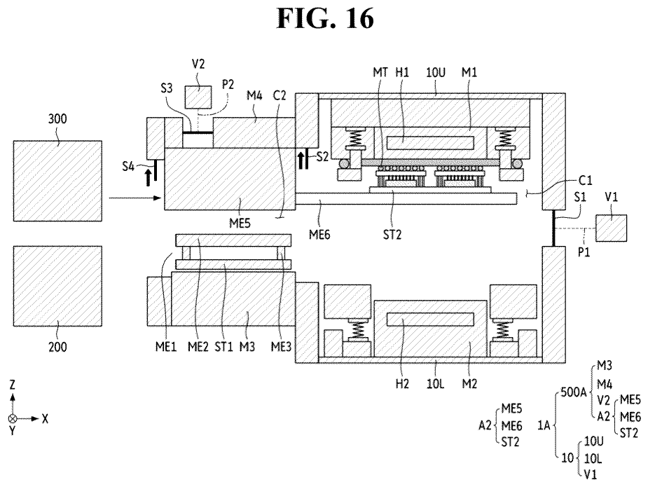

FIG. 16 is a diagram for explaining a second transfer arm of the preloader according to some embodiments.

Referring to FIG. 16, the preloader 500A of the semiconductor package molding apparatus 1A may further include a second transfer arm A2. The second transfer arm A2 may receive the molding target MT from the molding target transfer unit 300. At this time, the fourth shutter S4 may be opened. The second transfer arm A2 may include a fifth member ME5, a sixth member ME6, and a second stage ST2. The fifth member ME5 may be formed on the fourth mold M4. The sixth member ME6 may be mounted on the fifth member ME5 to slide in the first direction X from the fifth member ME5.

In some embodiments, the molding target MT transferred from the molding target transfer unit 300 into the preloader 500A may be seated on the fourth mold M4 by the fifth member ME5, or the sixth member ME6 mounted on the fifth member ME5 may slide from the fifth member ME5 in the first direction X and the molding target MT may be seated on the first mold M1 by the sixth member ME6.

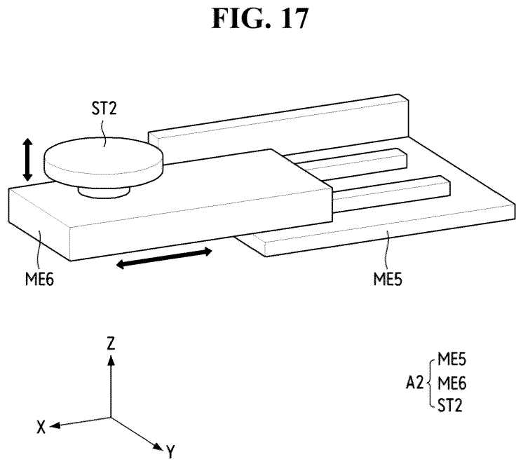

FIG. 17 is a diagram for explaining the second transfer arm of FIG. 16.

Referring to FIG. 17, the second stage ST2 may be disposed on the upper face of the sixth member ME6. The molding target MT (shown in FIG. 16) may be seated on the second stage ST2. In the state in which the molding target MT is seated on the second stage ST2, the sixth member ME6 mounted on the fifth member ME5 may slide from the fifth member ME5 along the first direction X. The sixth member ME6 may slide along the first direction X until the second stage ST2 is positioned below the first mold M1, and the second stage ST2 positioned below the first mold M1 may move along the third direction Z to seat the molding target MT on the first mold M1 (shown in FIG. 16).

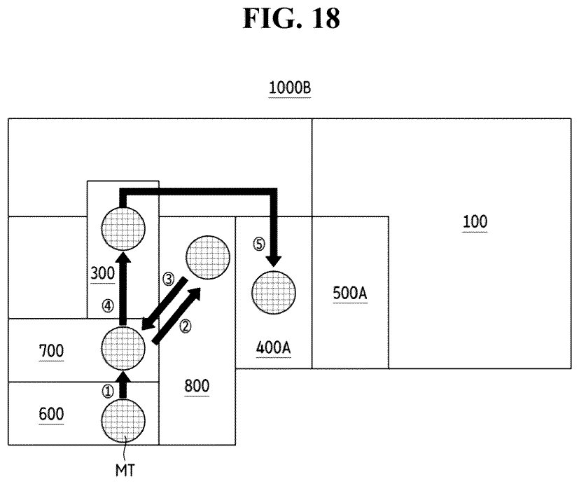

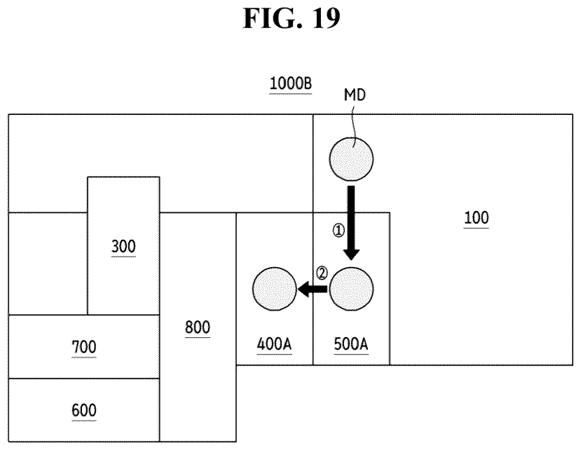

FIGS. 18 and 19 are diagrams showing each of a movement path of the molding target and a movement path of the molding material in the semiconductor package molding system according to some embodiments.

FIG. 18 shows the transfer path in which the molding target MT is carried from the load port 600 into the press unit 400A in a semiconductor package molding system 1000B. Referring to FIG. 18, the semiconductor package molding system 1000B may include a molding material discharge unit 100, a molding target transfer unit 300, a press unit 400A, a preloader 500A, a load port 600, a handler 700, and an aligner 800.

The molding target MT put into the semiconductor package molding system 1000B may be transferred to the aligner 800 from the load port 600 via the handler 700. The aligner 800 may receive and align the molding target MT from the handler 700. The molding target MT, after being aligned, may be transferred to the molding target transfer unit 300 by the handler 700. The molding target transfer unit 300 may transfer the molding target MT to the press unit 400A. That is, unlike the semiconductor package molding system 1000A of FIG. 2, in the semiconductor package molding system 1000B, the molding target transfer unit 300 may transfer the molding target MT immediately to the press unit 400A without going through the preloader 500A.

FIG. 19 shows a transfer path in which the molding material MD is carried from the molding material discharge unit 100 into the press unit 400A in the semiconductor package molding system 1000B. Referring to FIG. 19, the molding material MD is discharged from the molding material discharge unit 100 and immediately transferred to the preloader 500A. The preloader 500A may increase the vacuum level of the internal cavity of the preloader 500A to a target vacuum level, by using the vacuum unit (e.g., the vacuum), with the molding material MD being carried inside. Thereafter, when the vacuum degree of the cavity inside the preloader 500A reaches the target vacuum degree, the preloader 500A may transfer the molding material MD to the press unit 400A.

In this way, the molding target MT and the molding material MD may be provided inside the press unit 400A through the transfer paths of the molding target MT and the molding material MD shown in FIGS. 18 and 19, respectively. A compression molding process of encapsulating the molding target MT with the molding material MD may be performed in the press unit 400A.

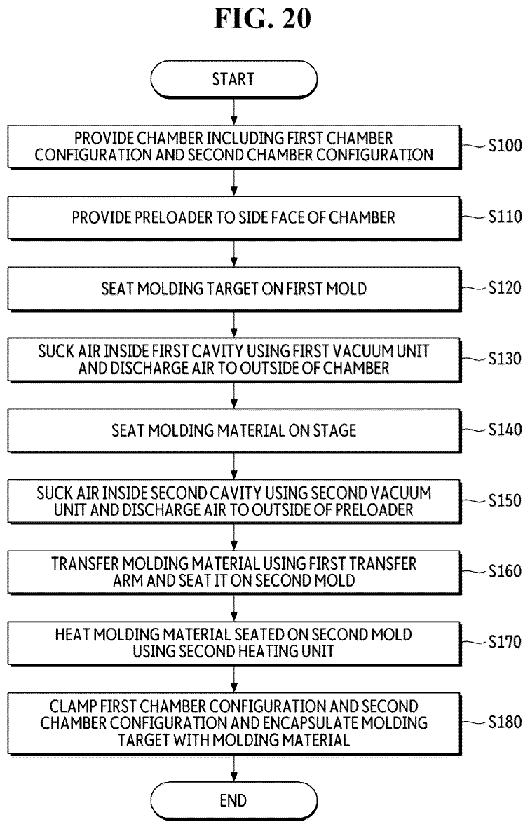

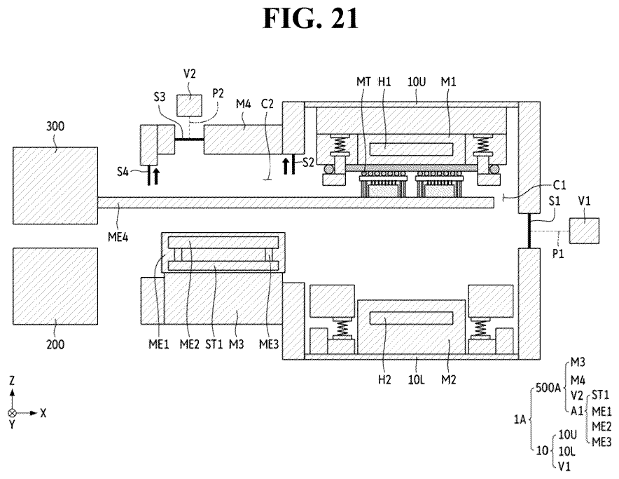

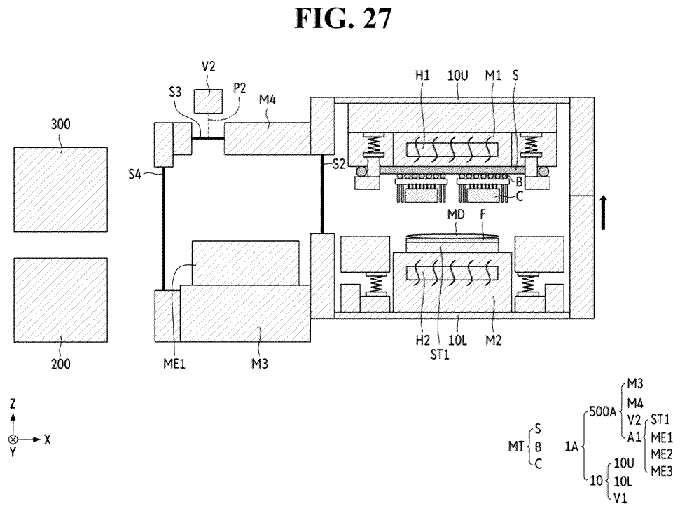

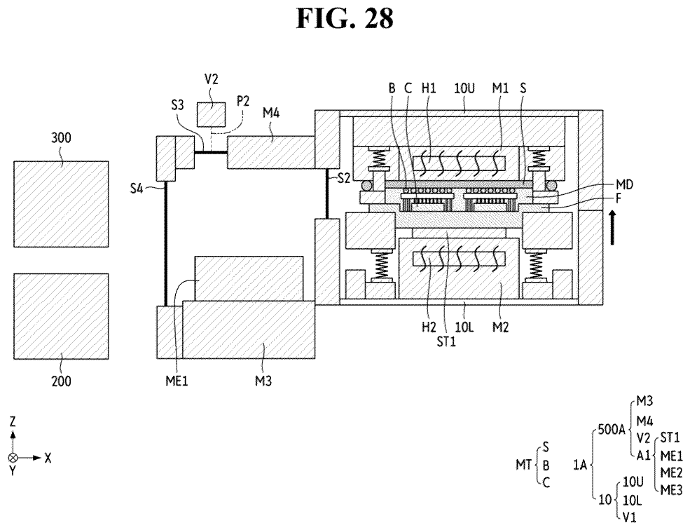

FIG. 20 is a flowchart for explaining a semiconductor package molding method according to some embodiments. FIGS. 21 to 28 are intermediate stage diagrams for explaining the semiconductor package molding method of FIG. 20. Hereinafter, the semiconductor package molding method according to some embodiments will be described with reference to FIGS. 20 to 28.

First, referring to FIGS. 20 and 21, the chamber 10 including the first chamber structure 10U and the second chamber structure 10L may be provided (operation S100), and the preloader 500A may be provided on the side face of the chamber 10 (operation S110). Then, the molding target MT may be seated on the first mold M1 of the first chamber structure 10U (operation S120). For example, in the state in which the molding target MT is seated on the upper face of the fourth member ME4 mounted on one side of the molding target transfer unit 300, the fourth member ME4 may slide from the molding target transfer unit 300 onto the first mold M1 along the first direction X. For example, the fourth member ME4 may slide maximally from the molding target transfer unit 300 along the first direction X, until the other end reaches the edge portion of the chamber 10. At this time, both the second shutter S2 and the fourth shutter S4 may be opened. The fourth member ME4 that has slid into the chamber 10 may seat the molding target MT on the first mold M1.

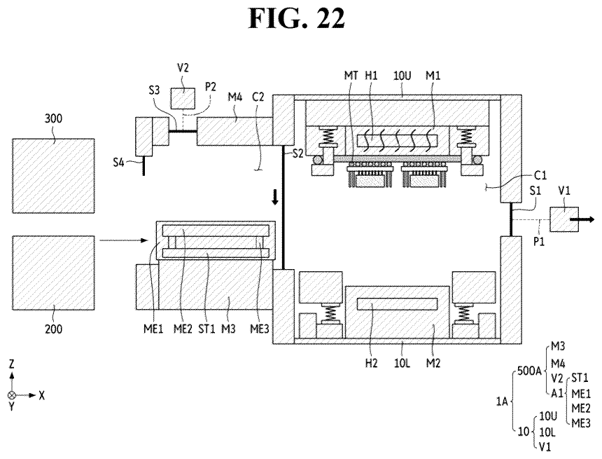

Next, referring to FIGS. 20 and 22, the second shutter S2 is closed, the first shutter S1 is opened, and then the air inside the first cavity C1 may be sucked using the first vacuum unit V1 and discharged to the outside of the chamber 10 (operation S130). At this time, the molding target MT seated on the first mold M1 may be in a state of being heated by the first heating unit H1. The first vacuum unit V1 may continue to perform decompression until the vacuum degree in the first cavity C1 reaches the first target vacuum degree.

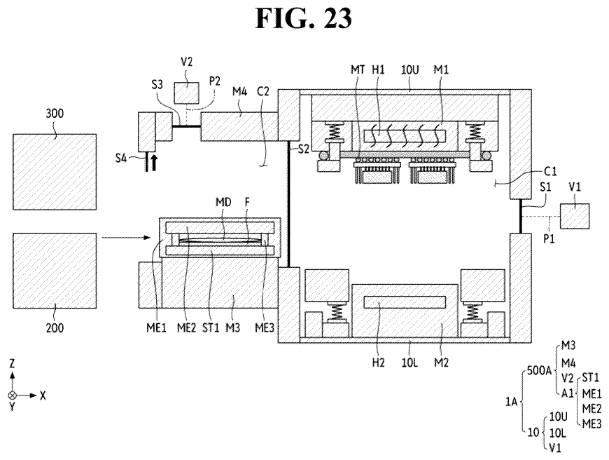

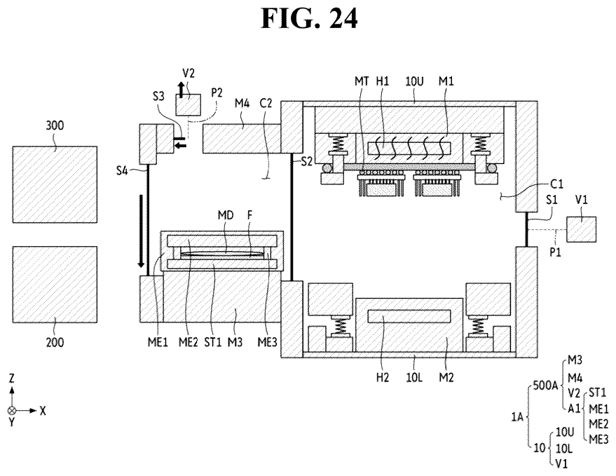

Next, referring to FIGS. 20 and 23, when the vacuum degree inside the first cavity C1 reaches the first target vacuum degree, the fourth shutter S4 may be opened, and the molding material transfer unit 200 may seat the molding material MD on the first stage ST1 (operation S140). At this time, the molding material MD may be disposed on the film F disposed on the upper face of the first stage ST1. Next, referring to FIGS. 20 and 24, after closing the fourth shutter S4 and opening the third shutter S3, the air inside the second cavity C2 may be sucked using the second vacuum unit V2 and discharged to the outside of the preloader 500A (operation S150). The second vacuum unit V2 may continue to perform decompression until the vacuum degree inside the second cavity C2 reaches the second target vacuum degree.

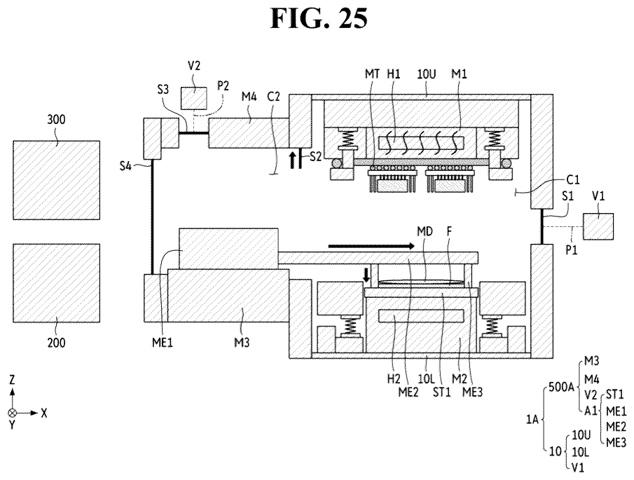

Next, referring to FIGS. 20 and 25, the second shutter S2 is opened, and the molding material MD is transferred into the chamber 10 using the first transfer arm A1, and the molding material MD may be seated on the second mold M2 (operation S160). That is, the second member ME2 slides from the first member ME1 along the first direction X, and the first stage ST1 that supports the molding material MD may move into the first cavity C1. When the first stage ST1 is disposed on the second mold M2, the third member ME3 may move in a direction opposite to the third direction Z to seat the molding material MD on the second mold M2.

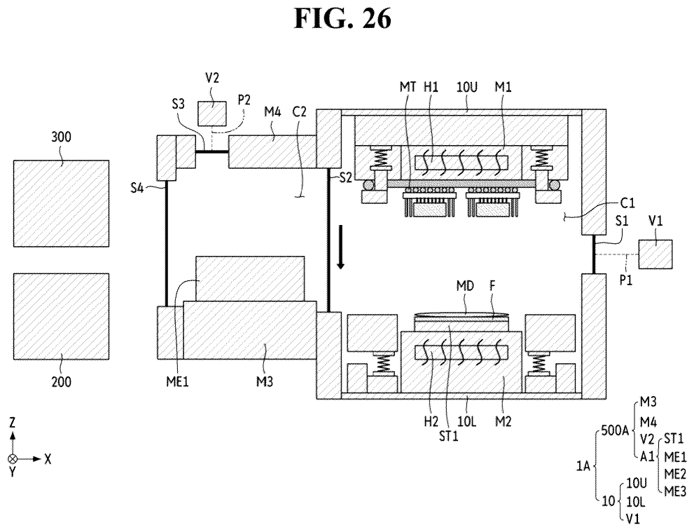

Next, referring to FIGS. 20 and 26, the second shutter S2 is closed, and the molding material MD seated on the second mold M2 may be heated, using the second heating unit H2 (operation S170). That is, the molding target MT seated on the first mold M1 and the molding material MD seated on the second mold M2 may be heated simultaneously by the first heating unit H1 and the second heating unit H2, respectively. At this time, the molding target MT seated on the first mold M1 is in the state of being continuously heated by the first heating unit H1 before the molding material MD is seated on the second mold M2. Therefore, the time period at which the molding target MT seated on the first mold M1 is heated by the first heating unit H1 may be longer than the time period at which the molding material MD seated on the second mold M2 is heated by the second heating unit H2.

Next, referring to FIGS. 20, 27, and 28, in the state in which the first chamber structure 10U is fixed, the second chamber structure 10L may move along the third direction Z to clamp the first chamber structure 10U and the second chamber structure 10L to each other, and the compression molding process may be performed, while encapsulating the molding target MT with the molding material MD (operation S180). At this time, while the molding material MD on the second mold M2 is being compressed, a MUF that covers the substrate S and the semiconductor chip C included in the molding target MT, and a plurality of bumps B between the substrate S and the semiconductor chip C may be formed.

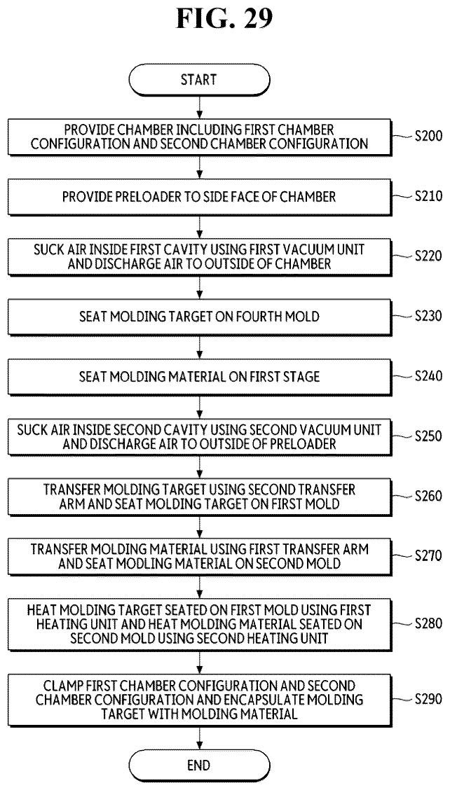

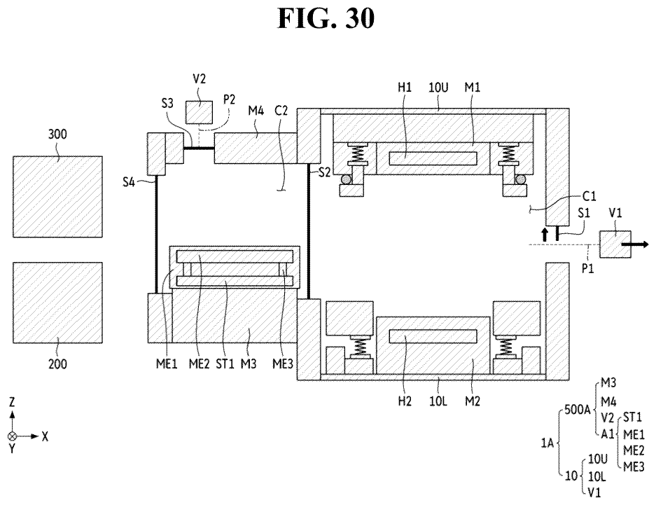

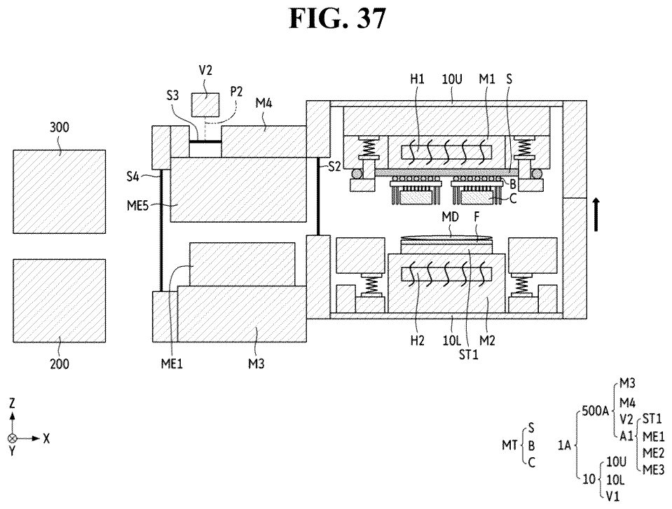

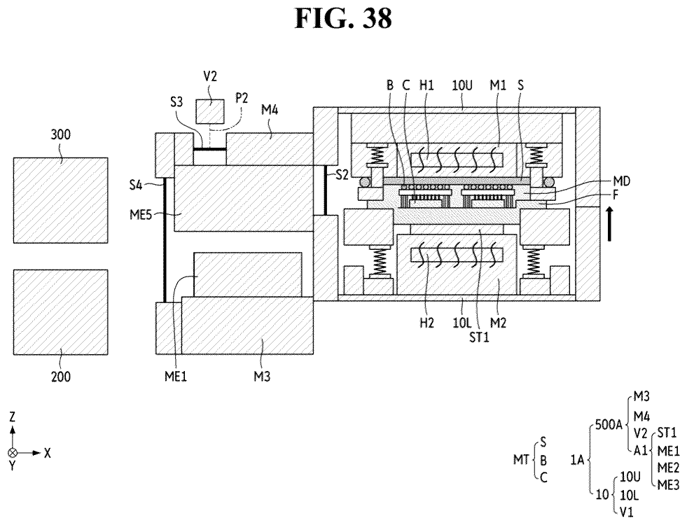

FIG. 29 is a flowchart for explaining a semiconductor package molding method according to some embodiments. FIGS. 30 to 38 are intermediate stage diagrams for explaining the semiconductor package molding method of FIG. 29. Hereinafter, the semiconductor package molding method according to some embodiments will be described with reference to FIGS. 29 to 38.

First, referring to FIGS. 29 and 30, the chamber 10 including the first chamber structure 10U and the second chamber structure 10L may be provided (operation S200), and the preloader 500A may be provided on the side face of the chamber 10 (operation S210). Then, air inside the first cavity C1 may be sucked using the first vacuum unit V1 and discharged to the outside of the chamber 10 (operation S220). At this time, the second shutter S2, the third shutter S3, and the fourth shutter S4 may all be in the closed state, and the first shutter S1 may be in the open state. The first vacuum unit V1 may continue to perform decompression, until the vacuum degree in the first cavity C1 reaches the first target vacuum degree.

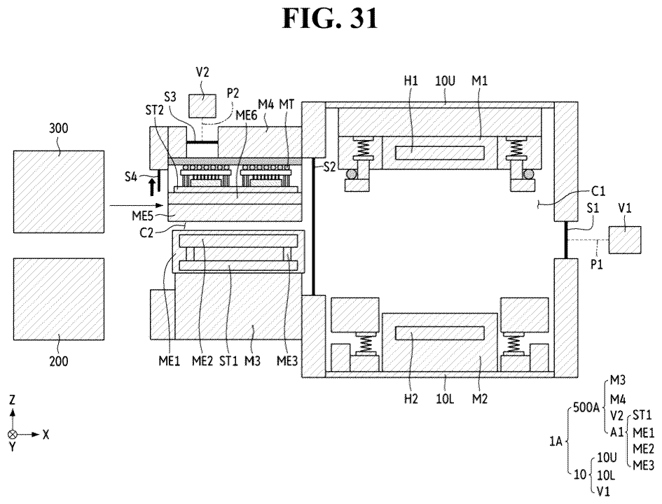

Next, referring to FIGS. 29 and 31, when the vacuum degree inside the first cavity C1 reaches the first target vacuum degree, the first shutter S1 may be closed and the fourth shutter S4 may be opened. Then, the second transfer arm A2 may receive the molding target MT from the molding target transfer unit 300. Also, the second transfer arm A2 may seat the molding target MT on the fourth mold M4 (operation S230).

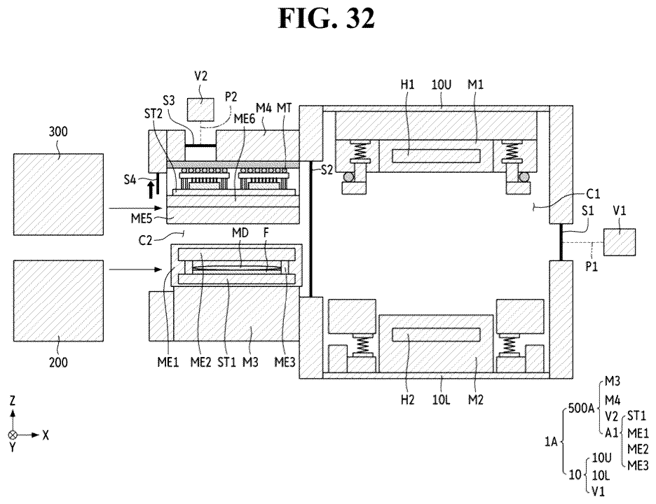

Next, referring to FIGS. 29 and 32, the molding material transfer unit 200 may seat the molding material MD on the first stage ST1 (operation S240). At this time, the molding material MD may be disposed on the film F disposed on the upper face of the first stage ST1.

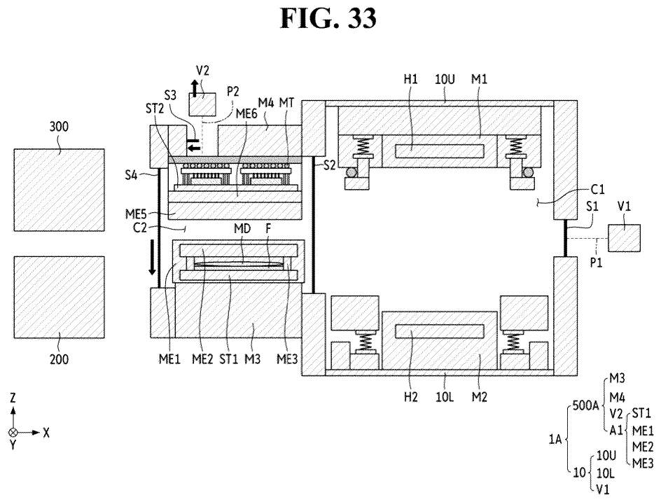

Next, referring to FIGS. 29 and 33, after closing the fourth shutter S4 and opening the third shutter S3, the air inside the second cavity C2 is sucked using the second vacuum unit V2, and may be discharged to the outside of the preloader 500A (operation S250). That is, in the state in which the molding target MT and the molding material MD are seated on each of the fourth mold M4 and the third mold M3 of the preloader 500A, the second vacuum unit V2 may continue to perform decompression, until the vacuum inside the second cavity C2 reaches the second target vacuum.

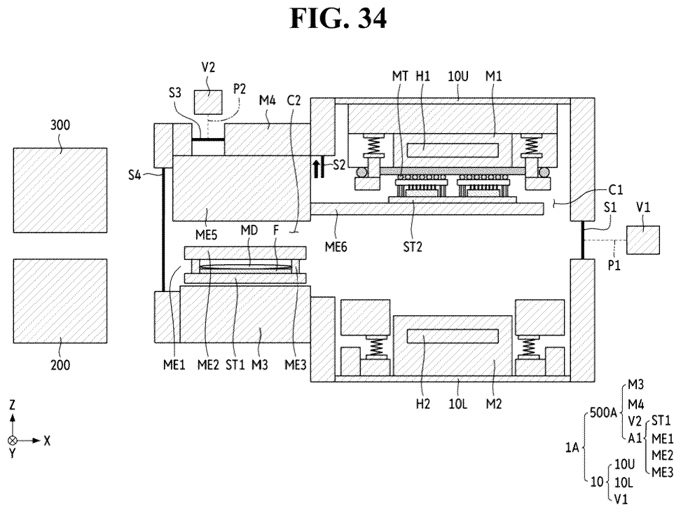

Next, referring to FIGS. 29 and 34, when the vacuum level inside the second cavity C2 reaches the second target vacuum level, the third shutter S3 may be closed, the second shutter S2 may be opened, and the molding target MT may be transferred into the chamber 10 using the transfer arm A2, and the molding target MT may be seated on the first mold M1 (operation S260). That is, the sixth member ME6 may slide from the fifth member ME5 along the first direction X to seat the molding target MT on the first mold M1.

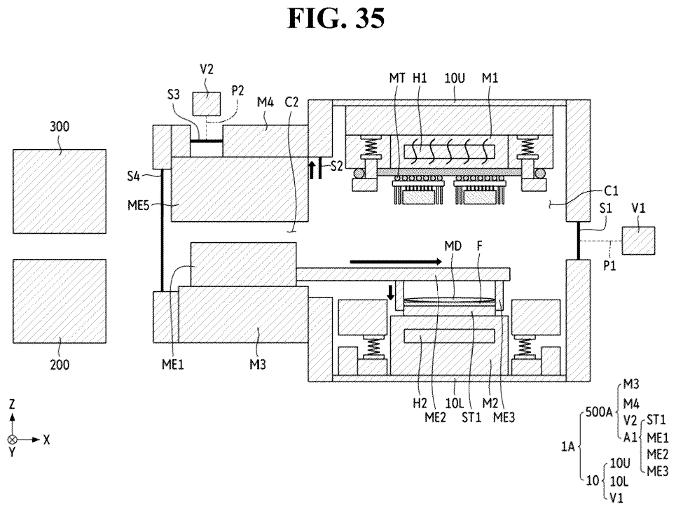

Next, referring to FIGS. 29 and 35, the molding material MD may be transferred into the chamber 10 using the first transfer arm A1, and the molding material MD may be seated on the second mold M2 (operation S270). Although a case in which the molding target MT is seated on the first mold M1 by using the second transfer arm A2, and then the molding material MD is seated to the second mold M2 by using the first transfer arm A1 is described above, embodiments of the present disclosure are not limited thereto. For example, in some embodiments, the molding material MD may be first seated on the second mold M2 by using the first transfer arm A1, and then the molding target MT may be seated on the first mold M1 by using the second transfer arm A2.

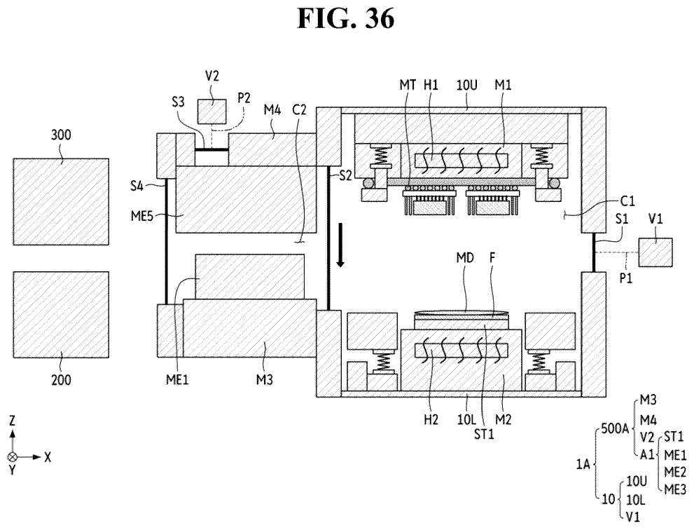

Next, referring to FIGS. 29 and 36, when the molding target MT and the molding material MD are seated on the first mold M1 and the second mold M2, respectively, the second shutter S2 is closed, and each of the molding target MT and the molding material MD may be heated using the first heating unit H1 and the second heating unit H2 (operation S280). For example, the molding target MT seated on the first mold M1 and the molding material MD seated on the second mold M2 may be in the state of being continuously heated from the time point at which they are each seated on the molds.

Next, referring to FIGS. 29, 37 and 38, in the state in which the first chamber structure 10U is fixed, the second chamber structure 10L may move along the third direction Z to clamp the first chamber structure 10U and the second chamber structure 10L to each other, and the compression molding process may be performed, while encapsulating the molding target MT with the molding material MD (operation S290). At this time, while the molding material MD on the second mold M2 is being compressed, a MUF that covers the substrate S and the semiconductor chip C included in the molding target MT, and the plurality of bumps B between the substrate S and the semiconductor chip C may be formed.

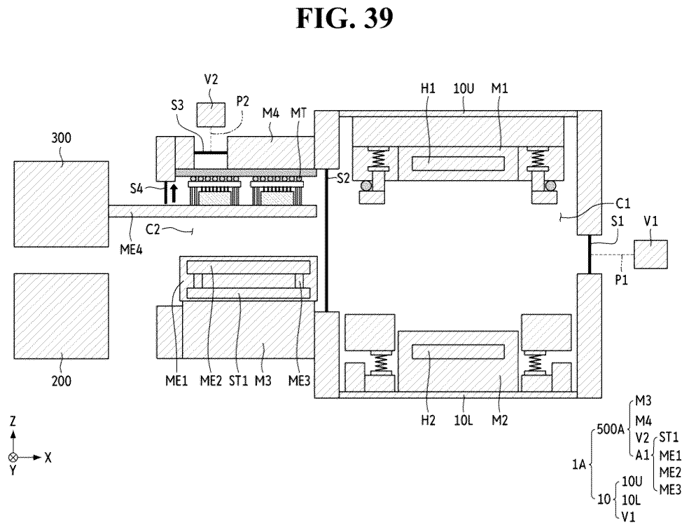

FIGS. 39 to 44 are intermediate stage diagrams for explaining the semiconductor package molding method of FIG. 29. Hereinafter, descriptions that are the same as or similar to the description of the previously-described embodiments may be omitted, and differences will be mainly explained.

First, referring to FIG. 39, unlike the embodiment described with reference to FIG. 31, when the molding target MT is seated on the fourth mold M4 of the preloader 500A, the fourth member ME4 mounted on the molding target transfer unit 300 may slide along the first direction X to seat the molding target MT on the fourth mold M4.

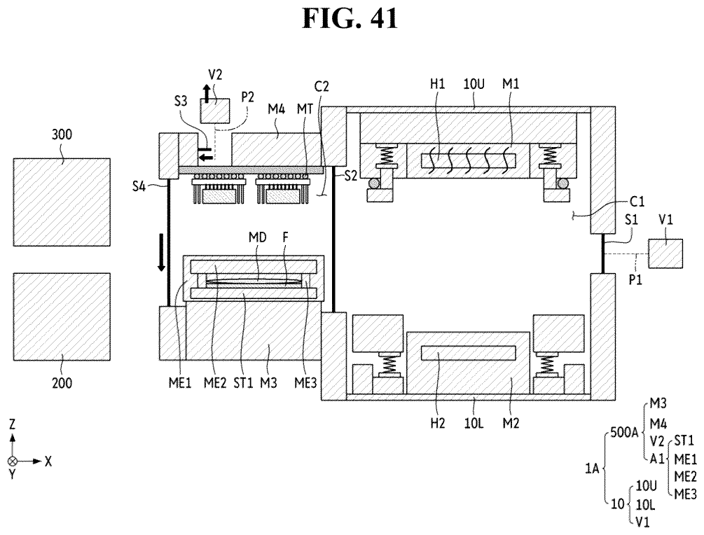

Next, referring to FIGS. 40 and 41, the molding material transfer unit 200 may seat the molding material MD on the film F disposed on the upper face of the first stage ST1, and then the shutter S4 is closed and the third shutter S3 is opened, and then the air inside the second cavity C2 is sucked using the second vacuum unit V2 and may be discharged to the outside of the preloader 500A. That is, in the state in which each of the molding target MT and the molding material MD is seated on the fourth mold M4 and the third mold M3 of the preloader 500A, the second vacuum unit V2 may continue to perform decompression, until the vacuum level in the second cavity C2 reaches the second target vacuum.

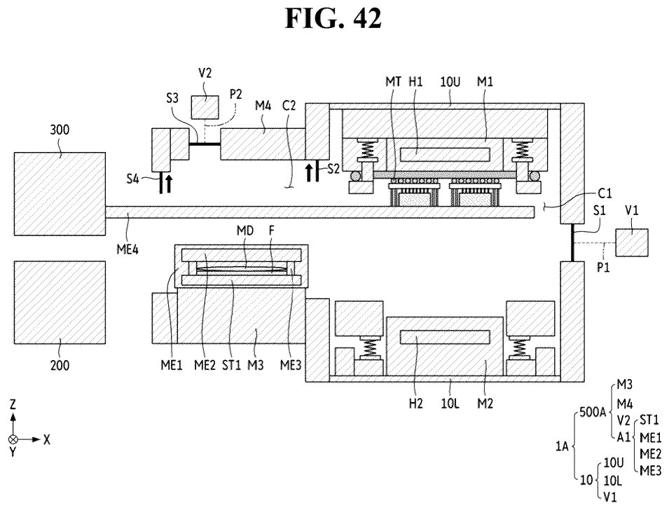

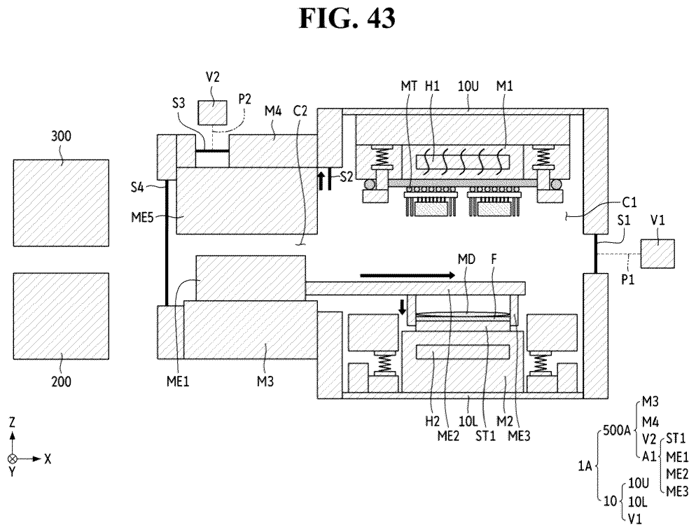

Next, referring to FIGS. 42 and 43, the fourth member ME4 slides maximally from the molding target transfer unit 300 along the first direction X, and the molding target MT may be seated on the first mold M1. Also, the molding material MD may be transferred into the chamber 10 using the first transfer arm A1, and the molding material MD may be seated on the second mold M2.

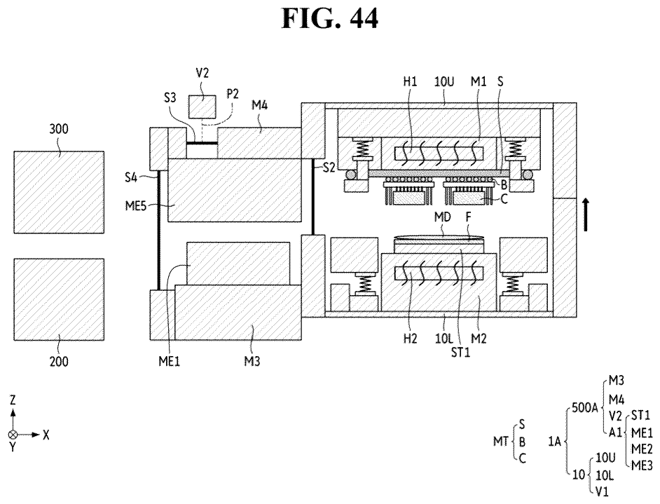

Next, referring to FIG. 44, when the molding target MT and the molding material MD are seated on the first mold M1 and the second mold M2, respectively, the second shutter S2 is closed, and each of the molding target MT and the molding material MD may be heated, using the first heating unit H1 and the second heating unit H2. After that, when the molding material MD is sufficiently heated and becomes a liquefied state having fluidity, the second chamber structure 10L moves along the third direction Z while the first chamber structure 10U is fixed, the first chamber structure 10U and the second chamber structure 10L may be clamped to each other, and the compression molding process may be performed, while the molding target MT is encapsulated with the molding material MD.

According to some embodiments of the present disclosure, the semiconductor package molding system (e.g., the semiconductor package molding system 1000A or the semiconductor package molding system 1000B) may further include a controller that is configured to control the semiconductor package molding system to perform the methods described above. For example, the controller may be configured to control the molding material discharge unit 100, the molding material transfer unit 200, the molding target transfer unit 300, the load port 600, the handler 700, the aligner 800, the press unit 400a, the press unit 400B, the preloader 500A, and/or the preloader 500B, including the components thereof, to perform their respective functions.

According to some embodiments of the present disclosure, the controller may include at least one processor and memory storing computer instructions. The computer instructions may be configured to, when executed by the at least one processor, cause the controller to perform its functions.

Although non-limiting example embodiments of the present disclosure have been described with reference to the accompanying drawings, embodiments of the present disclosure are not limited to the example embodiments, and may be implemented in various different forms. A person skilled in the art may appreciate that embodiments of the present disclosure may have other concrete forms without departing from the spirit and scope of the present disclosure. Therefore, it should be appreciated that the example embodiments as described above are not restrictive and are illustrative in all respects.

What is claimed is:

1. A semiconductor package molding apparatus comprising:
a chamber comprising:
a first chamber structure comprising a first mold on which a molding target is configured to be seated;
a second chamber structure configured to be clamped to the first chamber structure such as to isolate an interior of the chamber from an exterior of the chamber, the second chamber structure comprising a second mold comprising a first heater, wherein the first mold and the second mold are configured to form a first cavity between the first mold and the second mold; and
a first vacuum configured to discharge air from the first cavity; and
a preloader on a side face of the chamber, the preloader comprising:
a second cavity;
a third mold configured to have a molding material seated thereon;
a second vacuum configured to discharge air from the second cavity, and
a first transfer arm configured to seat the molding material on the second mold.

2. The semiconductor package molding apparatus of claim 1, wherein the chamber and the preloader are side by side with each other along a first direction, and
wherein the first transfer arm comprises:
a stage on which the molding material is configured to be seated;
a first member on the third mold; and
a second member mounted on the first member and configured to slide from the first member onto the second mold along the first direction.

3. The semiconductor package molding apparatus of claim 2, wherein the stage is on the second member and is configured to move from the second member in a second direction intersecting with the first direction.

4. The semiconductor package molding apparatus of claim 1, wherein the first heater is configured to heat the molding material seated on the second mold for a predetermined period of time.

5. The semiconductor package molding apparatus of claim 1, wherein the preloader further comprises a second transfer arm configured to seat the molding target on the first mold.

6. The semiconductor package molding apparatus of claim 5, wherein the preloader further comprises a fourth mold,
wherein the second cavity is between the third mold and the fourth mold, and
wherein the second transfer arm is further configured to seat the molding target on the fourth mold.

7. The semiconductor package molding apparatus of claim 6, wherein the chamber and the preloader are disposed side by side with each other along a first direction, and
wherein the second transfer arm comprises:
a first member on the fourth mold; and
a second member mounted on the first member and configured to slide onto the first mold from the first member along the first direction.

8. The semiconductor package molding apparatus of claim 1, wherein the third mold comprises a second heater, and the second heater is configured to heat the molding material seated on the third mold for a predetermined period of time.

9. A semiconductor package molding system comprising:
a molding material discharger configured to discharge and transfer a molding material;
a molding material transferor configured to receive and transfer the molding material from the molding material discharger;
a molding target transferor configured to transfer a molding target;
a presser configured to perform a compression molding process on the molding target, using the molding material; and
a preloader comprising:
a first cavity;
a stage on which the molding material is configured to be seated;
a first vacuum configured to discharge air from the first cavity; and
a first transfer arm configured to transfer the molding material to the presser,
wherein the presser comprises:
a first chamber structure comprising a first mold on which the molding target is configured to be seated;
a second chamber structure comprising a second mold comprising a heater, the first mold and the second mold configured to form a second cavity between the first mold and the second mold; and
a second vacuum configured to discharge air of the second cavity,
wherein the first chamber structure and the second chamber structure are configured to be clamped to each other to perform the compression molding process.

10. The semiconductor package molding system of claim 9, wherein the molding target transferor is further configured to carry the molding target into the presser without going through the preloader, and carry the molding material into the presser via the preloader.

11. The semiconductor package molding system of claim 9, wherein the molding target transferor is further configured to carry the molding target into the presser via the preloader, and carry the molding material into the presser via the preloader.

12. The semiconductor package molding system of claim 11, wherein the preloader further comprises a second transfer arm configured to seat the molding target on the first mold, and
wherein the second vacuum is configured to suck the air inside the first cavity and discharge the air to an outside of the first cavity, in a state in which the molding target is seated on the first mold.

13. The semiconductor package molding system of claim 11, wherein the preloader further comprises:
a third mold on which the molding material is configured to be placed;
a fourth mold; and
a second transfer arm configured to seat the molding target on at least one from among the first mold and the fourth mold, and
wherein the third mold and the fourth mold are configured to form the second cavity between the fourth mold and the third mold.

14. The semiconductor package molding system of claim 13, wherein the first vacuum is configured to suck the air inside the second cavity and discharge the air to the outside of the preloader, in a state in which the molding target is seated on the fourth mold, and the molding material is seated on the stage on the third mold.

15. A semiconductor package molding method comprising:
seating a molding material on a stage of a preloader, wherein the preloader is on a side face of a chamber, and the chamber includes a first chamber structure including a first mold, and a second chamber structure including a second mold including a first heater, wherein a first cavity is between the first mold and the second mold;
sucking, by a first vacuum of the preloader, air inside a second cavity of the preloader and discharging the air to an outside of the preloader;
transferring, by a first transfer arm of the preloader and after the sucking the air, the molding material seated on the stage to the second mold, such that the molding material is seated on the second mold;
heating, by the first heater, the molding material seated on the second mold for a first time period; and
clamping, after the heating for the first time period, the first chamber structure and the second chamber structure such that a molding target seated on the first mold is encapsulated with the molding material.

16. The semiconductor package molding method of claim 15, wherein the chamber further includes a second vacuum configured to discharge air inside the first cavity, and
the semiconductor package molding method further comprises:
seating the molding target on the first mold before the sucking the air inside the second cavity and the discharging the air to the outside of the preloader, and
sucking, by the second vacuum, the air inside the first cavity and discharging the air to an outside of the chamber, while the molding target is seated on the first mold.

17. The semiconductor package molding method of claim 15, wherein the preloader further includes:
a third mold on which the molding material is configured to be disposed; and
a fourth mold,
wherein the third mold and the fourth mold are configured to form the second cavity between the third mold and the fourth mold,
wherein the sucking of the air inside the second cavity and the discharging the air to the outside of the preloader comprises sucking, by the first vacuum, the air inside the second cavity and discharging the air to the outside of the preloader, while the molding target is seated on the fourth mold and the molding material is seated on the stage.

18. The semiconductor package molding method of claim 15, wherein the preloader further includes a second transfer arm configured to seat the molding target on the first mold, and
the semiconductor package molding method further comprises transferring, by the second transfer arm, the molding target from the second cavity to the first cavity and seating the molding target on the first mold.

19. The semiconductor package molding method of claim 18, wherein the chamber further includes:
a first shutter between the preloader and the chamber, the first shutter configured to separate the first cavity from the second cavity; and
a second vacuum configured to discharge air from the first cavity, and
the semiconductor package molding method further comprises:
separating the first cavity from the second cavity by closing the first shutter; and
sucking, by the second vacuum and after the separating the first cavity from the second cavity, the air inside the first cavity and discharging the air to an outside of the chamber, in a state in which the molding target is seated on the first mold.

20. The semiconductor package molding method of claim 15, wherein the first mold further includes a second heater, and
wherein the semiconductor package molding method further comprises: heating the molding target, by the second heater while the molding target is seated on the first mold, for a second time period,
wherein the second time period is longer than the first time period.
